(19) United States
(12) Patent Application Publication
(10) Pub. No.: US 2022/0344548 A1
(43) Pub. Date: Oct. 27, 2022

(54) LIGHT-EMITTING ELEMENT, LIGHT-EMITTING DEVICE, AND DISPLAY DEVICE

(71) Applicant: SHARP KABUSHIKI KAISHA, Sakai City, Osaka (JP)

(72) Inventors: KENICHI YOSHIMURA, Sakai City, Osaka (JP); TADASHI KOBASHI, Sakai City, Osaka (JP); TATSUYA RYOHWA, Sakai City, Osaka (JP); MAKOTO IZUMI, Sakai City, Osaka (JP)

(21) Appl. No.: 17/762,871

(22) PCT Filed: Oct. 1, 2019
(86) PCT No.: PCT/JP2019/038706

§ 371 Date: Mar. 23, 2022

(51) Int. Cl. H01L 33/50

(52) U.S. Cl. CPC H01L 33/504

(57) ABSTRACT

A light-emitting element according to the disclosure includes an anode electrode, a cathode electrode, and a first light-emitting layer that includes a plurality of first quantum dots and emits light of a first color. The first light-emitting layer is provided between the anode electrode and the cathode electrode, and each of the plurality of first quantum dots includes a compound containing each of three elements of Zn, Se, and Te. A combination of an average particle size of the plurality of first quantum dots and a composition ratio of the three elements is selected such that the peak wavelength of a light emission spectrum of the first light-emitting layer is greater than 394 nm and equal to or less than 474 nm.

### TECHNICAL FIELD

The disclosure relates to a light-emitting element, a light-emitting device, and a display device.

### BACKGROUND ART

Conventionally, development of a light-emitting element has been carried out using quantum dots, which are nano-sized semiconductor particles. In the development of such a light-emitting element, activities have been promoted to eliminate cadmium from the material of quantum dots in order to reduce an environmental load. For example, NPL 1 discloses a quantum dot having a core/shell structure of ZnSe/ZnS, and a light-emitting element using the quantum dot. Hereinafter, the light-emitting element using the quantum dots will be referred to as a “QLED (Quantum-dot Light Emitting Diode)”.

### CITATION LIST

### Non Patent Literature

NPL 1: APPLIED PHYSICS LETTERS 103,053106 (2013)

### SUMMARY OF INVENTION

### Technical Problem

The peak wavelength of light emitted by a currently used blue QLED is significantly far from an ideal peak wavelength of a blue color constituting one of the three primary colors of light, compared to the peak wavelength of light emitted by each of a red QLED and a green QLED. When such a blue QLED is used to form a light-emitting element, it is difficult to bring the color gamut of light emitted by the light-emitting element closer to an ideal width.

In light of the problem described above, the disclosure has been conceived. An object of the disclosure is to provide a light-emitting element having a wider color gamut of emitted light, and a light-emitting device and a display device using the light-emitting element.

### Solution to Problem

A light-emitting element according to an embodiment of the disclosure includes an anode electrode, a cathode electrode, and a first light-emitting layer including a plurality of first quantum dots and configured to emit light of a first color. The first light-emitting layer is provided between the anode electrode and the cathode electrode, and each of the plurality of first quantum dots contains a compound containing each of three elements of Zn, Se, Te. A combination of an average particle size of the plurality of first quantum dots and a composition ratio of the three elements is selected to cause a peak wavelength of a light emission spectrum of the first light-emitting layer to be greater than 394 nm and equal to or less than 474 nm.

### BRIEF DESCRIPTION OF DRAWINGS

FIG. 1 is a schematic cross-sectional view illustrating a display device according to a first embodiment.

FIG. 2 is a schematic cross-sectional view illustrating a light-emitting device including a light-emitting element according to the first embodiment.

FIG. 3 is a table showing characteristic values of a light-emitting device according to a second embodiment.

FIG. 4 is an xy chromaticity diagram showing a color gamut of a light-emitting device of Example 2-1.

FIG. 5 is a diagram showing BT.2020 coverage ratios according to Example 2-1.

FIG. 6 is a diagram showing the BT.2020 coverage ratios according to Example 2-2.

FIG. 7 is a diagram showing the BT.2020 coverage ratios according to Example 2-3.

FIG. 8 is a table showing characteristic values of a light-emitting device according to a third embodiment.

FIG. 9 is a diagram showing the BT.2020 coverage ratios according to Example 3-1.

FIG. 10 is a diagram showing the BT.2020 coverage ratios according to Example 3-2.

FIG. 11 is a diagram showing the BT.2020 coverage ratios according to Example 3-3.

FIG. 12 is a table showing characteristic values of a light-emitting device according to a fourth embodiment.

FIG. 13 is a diagram showing the BT.2020 coverage ratios according to Example 4-1.

FIG. 14 is a diagram showing the BT.2020 coverage ratios according to Example 4-2.

FIG. 15 is a diagram showing the BT.2020 coverage ratios according to Example 4-3.

### DESCRIPTION OF EMBODIMENTS

Embodiments and examples of the disclosure will be described below with reference to the drawings. Note that, in the drawings, identical or equivalent elements are denoted with identical reference signs. In each of the embodiments, descriptions of identical or equivalent configurations will not be repeated. Further, hereinafter, descriptions of above and below correspond to above and below in each of the drawings.

### First Embodiment

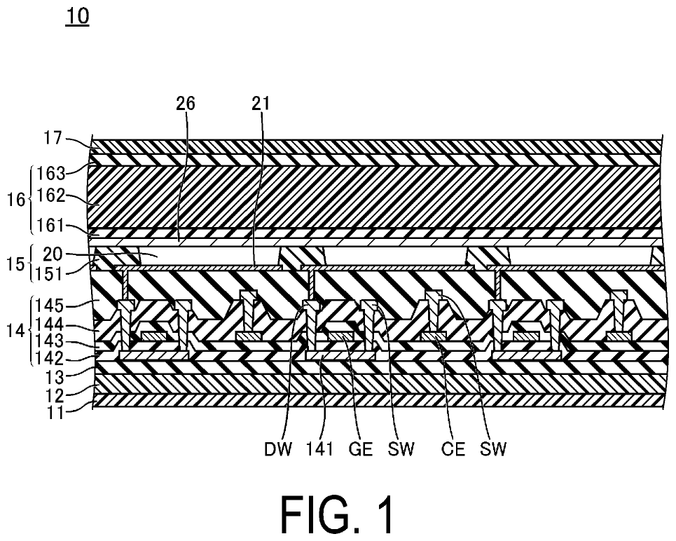

FIG. 1 is a cross-sectional view illustrating an outline of a display device 10 according to a first embodiment. The display device 10 of the present embodiment is a QLED panel, and includes a light-emitting element 20 including quantum dots.

In the display device 10, a resin layer 12 and a barrier layer 13 are layered in this order above a first film 11. A TFT layer 14 including a thin film transistor (hereinafter referred to as a “TFT (Thin Film Transistor)”) is provided above the barrier layer 13. A light-emitting element layer 15, which includes the light-emitting element 20 and a cover film 151, is provided above the TFT layer 14. A sealing layer 16 and a second film 17 are layered in this order above the light-emitting element layer 15.

The first film 11 is a support member that supports the display device 10 having flexibility. For example, the first film 11 can be constituted by a material having flexibility, such as PET (Poly-Ethylene Terephthalate). Note that when the display device 10 is not required to be flexible, a hard material such as glass may be used as the support member instead of the first film 11.

The resin layer 12 is provided between the first film 11 and the barrier layer 13. The resin layer 12 is a layer that is partially removed when a support substrate (not illustrated) is peeled off from the barrier layer 13. The resin layer 12 may have a structure in which a plurality of resin films are layered on each other. Further, the resin layer 12 may have a structure in which an inorganic film is interposed between the plurality of resin films. Note that when the display device 10 is not required to be flexible, the resin layer 12 need not necessarily be provided between the first film 11 and the barrier layer 13.

The barrier layer 13 is a layer for preventing foreign matter, such as water and oxygen, from entering the TFT layer 14 and the light-emitting element layer 15. The barrier layer 13 is a single layer or a multilayer insulating film. For example, each insulating film of the barrier layer 13 can be constituted by an insulating material such as silicon oxide, silicon nitride, or silicon oxynitride.

The TFT layer 14 is provided with a semiconductor film 141 and a gate insulating film 142 provided above the semiconductor film 141. A gate electrode GE and a gate wiring line (not illustrated) that is electrically connected to the gate electrode GE are provided above the gate insulating film 142. A first insulating film 143 is provided above the gate electrode GE and the gate wiring line. A capacitance electrode CE is provided above the first insulating film 143. A second insulating film 144 is provided above the capacitance electrode CE. A source wiring line SW and a drain wiring line DW (not illustrated) are provided above the second insulating film 144. A flattening film 145 is provided above the source wiring line SW and the drain wiring line DW.

The TFT layer 14 includes the semiconductor film 141, the gate insulating film 142, the gate electrode GE, the first insulating film 143, and the second insulating film 144. A source region and a drain region (not illustrated) are provided at the semiconductor film 141. Each of the source region and the drain region is a portion of an impurity region in which carriers are doped at a high concentration to a predetermined depth from the upper surface of the semiconductor film 141. A plurality of contact holes are provided so as to penetrate the layered three layers of the gate insulating film 142, the first insulating film 143, and the second insulating film 144, and to extend in the layering direction. The gate electrode GE is electrically connected to the gate wiring line (not illustrated). The gate wiring line is electrically connected to a driver IC (Integration Circuit) (not illustrated). Of the plurality of contact holes, a pair of the contact holes provided at both sides of the gate electrode GE are filled with the source wiring line SW and the drain wiring line DW, respectively. The source wiring line SW is electrically connected to the source region and the driver IC (not illustrated). The drain wiring line DW is electrically connected to the drain region and a pixel electrode (not illustrated).

For example, the semiconductor film 141 can be constituted by a semiconductor material such as a low-temperature polysilicon and an oxide semiconductor. The gate electrode GE, the gate wiring line, the capacitance electrode CE, and the drain wiring line DW and the source wiring line SW can be each constituted by a single layer or a multilayer conductive film.

The first insulating film 143 and the second insulating film 144 can be each constituted by a single layer or a multilayer insulating film. The first insulating film 143 and the second insulating film 144 can be each constituted by an insulating material such as silicon oxide and silicon nitride.

The TFT is a switching element that controls light emission of the light-emitting element 20. One of the TFTs is electrically connected to one of the light-emitting elements 20. Although a top gate TFT is used in FIG. 1, a bottom gate TFT or a double gate TFT may be used instead.

The flattening film 145 is a film having an upper surface formed in a planar shape, and is provided above the plurality of the TFTs. The flattening film 145 is layered above the TFTs so as to cover recesses and protrusions present in the surface shape of the TFT structure. The light-emitting element layer 15 including the light-emitting element 20 can be layered above the flattening film 145. In FIG. 1, the contact holes penetrate the flattening film 145 in the thickness direction thereof. The contact hole is filled with a conductive member. The drain region and an anode electrode 21 are electrically connected to each other via the conductive member of the contact hole and the drain wiring line DW.

The light-emitting element layer 15 is provided with a plurality of the light-emitting elements 20 and with the cover film 151. The plurality of light-emitting elements 20 constitute a display region of the display device 10 in a state in which the plurality of light-emitting elements 20 are arranged in a matrix shape. The cover film 151 is a film provided between the plurality of light-emitting elements 20. The cover film 151 covers side surfaces of each of the light-emitting elements 20 and end portions of each of the anode electrodes 21. The cover film 151 is an insulating film. For example, the cover film 151 can be constituted by an organic material.

FIG. 1 illustrates a structure, as an example, in which the plurality of light-emitting elements 20 share one cathode electrode 26. The shape of the cathode electrode 26 is not limited to the structure described above. For example, a structure may be employed in which the plurality of light-emitting elements 20 are electrically connected to a plurality of the cathode electrodes 26, respectively. In FIG. 1, the plurality of light-emitting elements 20 are electrically connected to a plurality of the anode electrodes 21, respectively, but the shape of the anode electrode 21 is not limited to the structure described above. For example, a structure may be employed in which the plurality of light-emitting elements 20 share one of the anode electrodes 21.

The sealing layer 16 is a layer for preventing foreign matter, such as water and oxygen, from entering the TFT layer 14 and the light-emitting element layer 15. FIG. 1 illustrates, as an example, the sealing layer 16 having a three-layer structure. The sealing layer 16 includes a first sealing film 161 covering the cathode electrode 26, a second sealing film 162 covering the first sealing film 161, and a third sealing film 163 covering the second sealing film 162. For example, the first sealing film 161 and the third sealing film 163 are each a single-layer or a multilayer light-transmissive inorganic insulating film. The first sealing film 161 and the third sealing film 163 can be each constituted by a material such as a silicon oxide film, a silicon nitride film, or a silicon oxynitride film. The second sealing film 162 is, for example, a light-transmissive organic film. The second sealing film 162 can be constituted by a material such as acrylic. The sealing layer 16 is not limited to the three-layer structure. The sealing layer 16 can be constituted by any number of layers, including a single layer.

The second film 17 is a member that protects the surface of the display device 10. For example, the second film 17 can be constituted by a material having flexibility, such as PET. By including the second film 17 as a surface protection member, the display device 10 having flexibility can be realized. Note that when the display device 10 is not required to be flexible, a hard material such as glass may be used as the surface protection member instead of the second film 17.

Of the first film 11 and the second film 17, a film provided on a light emission side of the light-emitting element 20 is disposed on a side of the display region of the display device 10. For example, a function film having an optical compensation function, a touch sensor function, a protection function, or the like may be used as the film on the display region side.

The light-emitting element 20 according to the present embodiment emits light from the anode electrode 21 to the outside of the display device 10, via the first film 11, the resin layer 12, the barrier layer 13, and the TFT layer 14. In this case, the first film 11, the resin layer 12, the barrier layer 13, and the TFT layer 14 are each preferably a material having high light-transmissivity. Further, at least one of the sealing layer 16 and the second film 17 preferably has a light reflecting function.

The light-emitting element 20 may emit the light from the cathode electrode 26 to the outside of the display device 10 via the sealing layer 16 and the second film 17. In this case, the sealing layer 16 and the second film 17 are each preferably a material having high light-transmissivity. Further, at least one of the first film 11, the resin layer 12, the barrier layer 13, and the TFT layer 14 preferably has the light reflecting function.

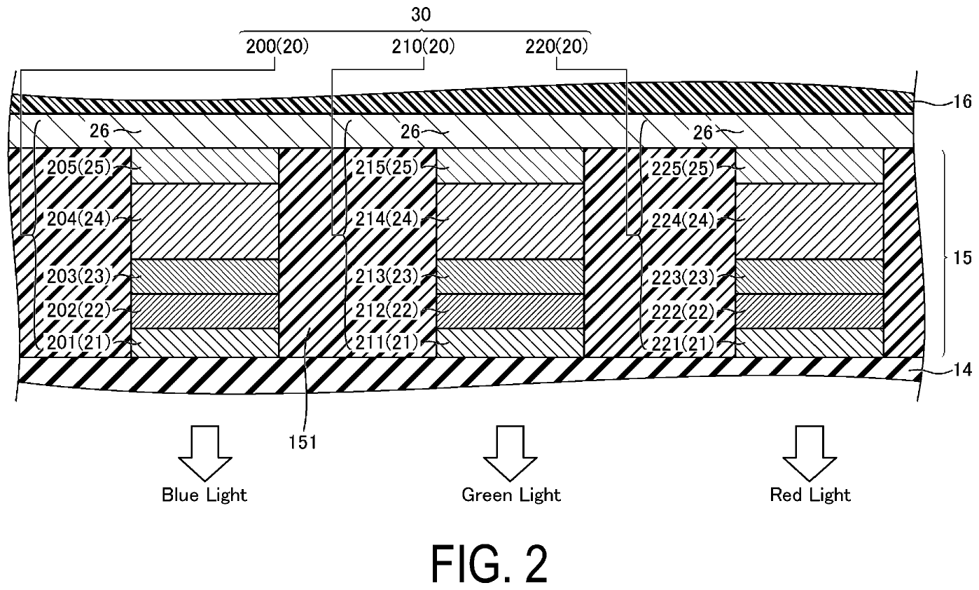

When the light is emitted from the light-emitting element 20 to the cathode electrode 26 side, an electron transport layer 25 (see FIG. 2) described below, and the cathode electrode 26 are each preferably constituted by a material having high light-transmissivity. For example, if the material has a transmittance of 95% or more with respect to visible light, attenuation of the light due to the electron transport layer 25 and the cathode electrode 26 can be made extremely small. Further, when a hole injection layer 22 (see FIG. 2) described below, a hole transport layer 23 (see FIG. 2) described below, and the electron transport layer 25 are each constituted by a material having an optical absorption coefficient of 10 cm⁻¹ or less with respect to emission light, luminous efficiency of the light-emitting element 20 can be increased.

On the outer side of the display region of the display device 10, a power supply circuit (not illustrated) and a light emission control circuit (an IC chip, a driver IC, a FPC, and the like) (not illustrated) are installed. A structure including the TFT and the light-emitting element 20 is considered to be one pixel. A group of the pixels is arrayed in a matrix shape on a plane and constitutes the display region of the display device 10. The above-described power supply circuit controls power supply to each of the pixels in the group. The light emission control circuit controls the light emission of each of the pixels in the group. According to the configuration described above, a display mode on a screen of the display device 10 is controlled.

FIG. 2 is a schematic cross-sectional view illustrating a light-emitting device 30 according to the first embodiment. FIG. 2 illustrates a portion of the TFT layer 14, the light-emitting device 30 provided above the TFT layer 14, and a portion of the sealing layer 16 provided above the light-emitting device 30 of the display device 10. The light-emitting device 30 includes the plurality of light-emitting elements 20. The light-emitting device 30 according to the present embodiment includes a set of three types of the light-emitting elements 20, namely, a first light-emitting element 200, a second light-emitting element 210, and a third light-emitting element 220. The light-emitting device 30 is formed above the TFT layer 14. A plurality of the light-emitting devices 30 are arrayed in a matrix shape in a plane and constitute a display screen of the display device 10. An image is displayed on the display screen of the display device 10.

The first light-emitting element 200 is constituted by layering an anode electrode 201, a hole injection layer 202, a hole transport layer 203, a first light-emitting layer 204, an electron transport layer 205, and the cathode electrode 26 in this order above the TFT layer 14. The first light-emitting layer 204 emits light of a first color.

The anode electrode 201 and the cathode electrode 26 are each constituted by a conductive material. Of the anode electrode 201 and the cathode electrode 26, an electrode disposed at a position from which light is emitted is preferably constituted by a conductive material having light-transmissivity. Examples of the conductive material having light-transmissivity include ITO, IZO, ZnO, AZO, BZO, and FTO. Of the anode electrode 201 and the cathode electrode 26, an electrode disposed at a position from which light is not emitted is preferably constituted by a conductive material having high reflectivity. As the conductive material having high reflectivity, a metal having high reflectivity such as Al, Cu, Au, Ag, or Mg is preferably employed. As the conductive material having high reflectivity described above, an alloy formed from two or more types of metal materials selected from Al, Cu, Au, Ag, and Mg may also be employed. By the electrode reflecting the light in a light emission direction, light emission efficiency of the first light-emitting element 200 is improved. In the present embodiment, an example is illustrated in which the anode electrode 201 is constituted by a light-transmissive material, and the cathode electrode 26 is constituted by a conductive material having high reflectivity. In this case, as indicated by a white arrow in FIG. 2, the light of the first color emitted from the first light-emitting layer 204 is transmitted from the anode electrode 201 to the TFT layer 14, and then emitted to the outside of the display device 10.

The anode electrode 201 is directly connected to the hole injection layer 202. The cathode electrode 26 is directly connected to the electron transport layer 205. The hole injection layer 202 is a layer for efficiently capturing positive holes from the anode electrode 201. The hole transport layer 203 is a layer for transporting the positive holes from the hole injection layer 202 to the first light-emitting layer 204. Note that the hole injection layer 202 and the hole transport layer 203 may be omitted. For example, only the hole injection layer 202 may be sandwiched between the anode electrode 201 and the first light-emitting layer 204, or the anode electrode 201 and the first light-emitting layer 204 may be directly connected to each other.

The hole injection layer 202 and the hole transport layer 203 can be each constituted by a material commonly used for the QLED, an organic EL element, and the like. For example, the hole injection layer 202 and the hole transport layer 203 can be each constituted by a conductive compound such as PEDOT-PSS, TFB, or PVK. Further, the hole injection layer 202 and the hole transport layer 203 may also be each constituted by an inorganic material such as NiO, Cr₂ O₃, MgO, MgZnO, LanO₃, MoO₃, and WO₃.

The first light-emitting layer 204 is a layer including a plurality of first quantum dots. The first light-emitting layer 204 has a single-layer structure of the quantum dots. Further, the first light-emitting layer 204 may have a multilayer structure in which a plurality of quantum dot layers are stacked. The plurality of first quantum dots included in the first light-emitting layer 204 are constituted by a compound containing three types of elements of Zn, Se, and Te. Furthermore, the quantum dot may have a core/shell structure in which a shell is provided at the outer periphery of a core. The core/shell structure is preferable in terms of both the luminous efficiency and durability. In the present specification, when the quantum dot is provided with the shell, the “quantum dot” can be read as the “core of the quantum dot”. A shell material is preferably a material having a larger band gap than that of a core material, and, for example, ZnS is suitably used. The particle diameter of the plurality of first quantum dots and a composition ratio of each of the elements are selected such that the peak wavelength of the light of the first color emitted by the first color of light-emitting layer 204 is greater than 394 nm and equal to and less than 474 nm. The peak wavelength refers to a highest value among a distribution of output values of a spectrum of the light emitted from the first light-emitting layer 204. The first light-emitting element 200 according to the present embodiment is commonly used as a light source of blue light.

The composition ratio of the three types of elements of Zn, Se and Te in the compound contained in the plurality of first quantum dots can be measured by an elementary analysis using an Energy Dispersive X-ray Spectrometry (EDX).

The compound, which is the material of the plurality of first quantum dots, is substantially constituted by the three elements of Zn, Se and Te, and may contain unavoidable impurities. Here, the unavoidable impurities refer to impurities that are unavoidably contained in a raw material or mixed in during a manufacturing process, and that cannot be excluded even if it is attempted to exclude them. In the present embodiment, the concentration of unavoidable impurities in the compound is 100 ppm or less. The concentration of unavoidable impurities may be any value as long as the peak wavelength of the light of the first color emitted by the first light-emitting layer 204 is in the vicinity of greater than 394 nm and equal to or less than 474 nm. The concentration of unavoidable impurities can be measured by a technique similar to the elementary analysis described above.

An average particle size of the plurality of first quantum dots is preferably in a range from 3 nm to 5 nm. In the above-described range, even if the composition ratio of each of the elements constituting the plurality of first quantum dots is changed over a wide range, the peak wavelength of the light of the first color emitted by the first light-emitting layer 204 can be caused to be greater than 394 nm to equal to or less than 474 nm.

The average particle size of the plurality of first quantum dots is measured using a Transmission Electron Microscope (TEM) at a cross-section, of the first light-emitting layer 204, taken along a direction from the anode electrode 201 toward the cathode electrode 26. Assuming that a particle of the quantum dot or of the quantum dot provided with the shell is a sphere, in the cross-sectional TEM measurement, one circular image is obtained for each of the particles. For example, approximately 500 samples are selected from the images of the particles of the quantum dots, and the diameters of the circular images of the individual samples are measured by image analysis. When the quantum dot is provided with the shell, the diameter of the core alone is measured using a difference in contrast between the core and the shell of the quantum dot in the particle image. The median value of the diameters of those samples is calculated as the average particle size of the quantum dots.

The electron transport layer 205 is a layer for transporting electrons from the cathode electrode 26 to the first light-emitting layer 204. One surface of the electron transport layer 205 is connected to the first light-emitting layer 204, and the other surface thereof is connected to the cathode electrode 26. For example, a material such as an organic matter containing a conductive material and a conductive inorganic matter can be employed for the electron transport layer 205. When the thickness of the electron transport layer 205 is less than 1 nm, the electron transport layer 205 becomes a discrete island-shaped layer. When the electron transport layer 205 is the island-shaped layer, an electrical connection between the electron transport layer 205 and the first light-emitting layer 204 becomes insufficient. Conversely, when the electron transport layer 205 is thick, the series resistance increases, and the power consumption of the first light-emitting element 200 increases. Thus, the thickness of the electron transport layer 205 is preferably approximately from 1 to 100 nm.

When a voltage is applied between the anode electrode 201 and the cathode electrode 26, the positive holes are injected from the anode electrode 201 side toward the first light-emitting layer 204, and the electrons are injected from the cathode electrode 26 side. The positive holes reach the first light-emitting layer 204 via the hole injection layer 202 and the hole transport layer 203. The electrons reach the first light-emitting layer 204 via the electron transport layer 205. The positive holes and the electrons that have reached the first light-emitting layer 204 are recombined inside the quantum dots, and the light of the first color is emitted from the first light-emitting layer 204 to the outside.

The second light-emitting element 210 and the third light-emitting element 220 according to the present embodiment include a second light-emitting layer 214 and a third light-emitting layer 224, respectively. The second light-emitting layer 214 emits light of a second color. The third light-emitting layer 224 emits light of a third color. The second light-emitting element 210 can be commonly used as a light source of green light. The third light-emitting element 220 can be commonly used as a light source of red light.

Of the second light-emitting element 210, layers other than the second light-emitting layer 214 have the same configuration as those of the first light-emitting element 200 described above. Of the third light-emitting element 220, layers other than the third light-emitting layer 224 have the same configuration as those of the first light-emitting element 200 described above. The second light-emitting element 210 is constituted by layering an anode electrode 211, a hole injection layer 212, a hole transport layer 213, the second light-emitting layer 214, an electron transport layer 215, and the cathode electrode 26 in this order on the TFT layer 14. The third light-emitting element 220 is constituted by layering an anode electrode 221, a hole injection layer 222, a hole transport layer 223, the third light-emitting layer 224, an electron transport layer 225, and the cathode electrode 26 in this order on the TFT layer 14.

Light-emitting diodes, organic ELs, QLEDs, or the like may be employed as the second light-emitting element 210 and the third light-emitting element 220. When the second light-emitting element 210 and the third light-emitting element 220 are the QLEDs, for example, a plurality of second quantum dots included in the second light-emitting layer 214 or a plurality of third quantum dots included in the third light-emitting layer 224 may each be constituted by one or more of substances selected from the group consisting of CdS, CdSe, CdTe, CuInS₂, ZnSe, ZnTe, Zn(Se, Te), InN, InP, InAs, InSb, AlP, AlS, AlAs, AlSb, GaN, GaP, GaAs, GaSb, PbS, PbSe, Si, Ge, MgS, MgSe, and MgTe.

Note that a material containing no cadmium is preferably used as the material of the plurality of first to third quantum dots included in the light-emitting device 30. If the quantum dots do not contain highly toxic cadmium, the light-emitting device 30 having a small environmental load can be configured.

In addition to the configuration described above, for example, in the second light-emitting element 210 or the third light-emitting element 220, a color filter may be provided on the light emission side of a white light-emitting element, and the color filter may be configured to convert white light into the light of the second color or the light of the third color. At least one of the second light-emitting element 210 and the third light-emitting element 220 may have a configuration in which a phosphor provided on the light emission side of the first light-emitting element 200 converts the wavelength of the light of the first color into the light of the second color or the light or the third color.

### Second Embodiment

A second embodiment of the disclosure will be described below. In the present embodiment, descriptions of the same configurations as those of the first embodiment will be omitted as appropriate.

In the light-emitting device 30 according to the second embodiment, the average particle size of the plurality of first quantum dots included in the first light-emitting element 200 is 3 nm. The composition formula of the compound constituting the plurality of first quantum dots included in first light-emitting layer 204 is ZnSeₓTe₁₋ₓ. x is a value greater than 0 and smaller than 1. By changing the value of x in a range from 0 to 1, the composition of the compound constituting the plurality of first quantum dots is adjusted. When x=0, the composition of the compound constituting the plurality of first quantum dots is ZnTe, and when x=1, it is ZnSe.

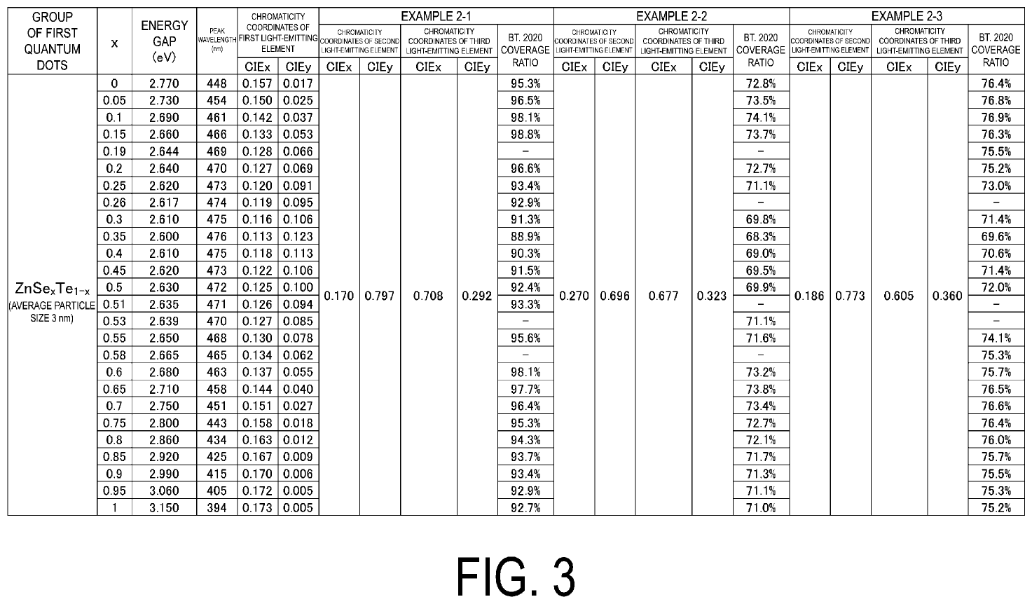

FIG. 3 shows characteristic values of the light emitted by the first light-emitting element 200 when the value of x is changed. The characteristic values of the first light-emitting element 200 shown in FIG. 3 are the energy gap (the unit is eV, and hereinafter is denoted by “Eg”), the peak wavelength (the unit is nm, and hereinafter is denoted by “λ”), and chromaticity coordinates that are based on the CIE standard colorimetric system (CIEx, CIEy).

When x=0, the composition of the plurality of first quantum dots is ZnTe, Eg=2.770 eV, λ=448 nm, and (CIEx, CIEy)=(0.162, 0.013).

When x=0.05, the composition of the plurality of first quantum dots is ZnSe_{0.05}Te_{0.95}, Eg=2.730 eV, λ=454 nm, and (CIEx, CIEy)=(0.150, 0.025).

When x=0.1, the composition of the plurality of first quantum dots is ZnSe_{0.10}Te_{0.90}, Eg=2.690 eV, λ=461 nm, and (CIEx, CIEy)=(0.142, 0.037). In this way, as the value of x changes, the energy gap, the peak wavelength, and the chromaticity coordinates change.

When x=1, the composition of the plurality of first quantum dots is ZnSe, Eg=3.150 eV, λ=394 nm, and (CIEx, CIEy)=(0.173, 0.005).

FIG. 3 shows relationships between color coordinates and coverage ratios in Example 2-1, Example 2-2, and Example 2-3, which are each an example of the present embodiment. FIG. 3 shows the chromaticity coordinates (CIEx, CIEy) of the second light-emitting element 210 and the third light-emitting element 220, and BT (Broadcasting service Television).2020 coverage ratios corresponding to the values of x in each of the examples. The BT.2020 coverage ratio is a ratio set under international standards of specifications that are required to be satisfied by ultra high definition televisions (UHDTV) having 4K and 8K resolutions. The light-emitting device 30 that can improve the BT.2020 coverage ratio will be exemplified below.

As will be described below, in a section in which a color gamut of light emitted by the light-emitting device 30 when the value of x is fixed overlaps with an ideal color gamut specified by BT.2020, the BT.2020 coverage ratio refers to a proportion, of the area of the ideal color gamut, that is occupied by the area of the overlapping section. The greater the BT.2020 coverage ratio of the light-emitting device 30, the greater a variety of colors that can be accurately reproduced by the display device 10 compatible with BT.2020.

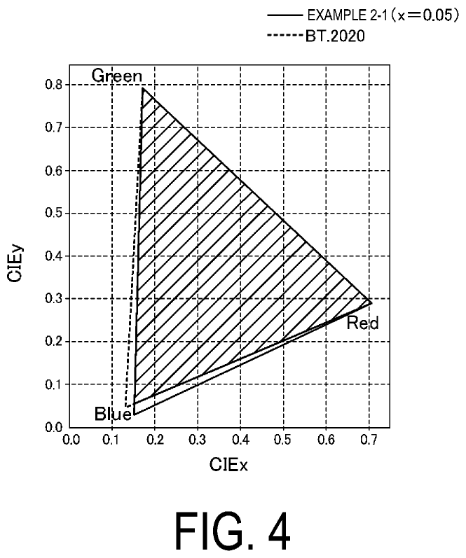

In FIG. 4, the chromaticity coordinates (CIEx, CIEy) of light emitted by each of the first light-emitting element 200, the second light-emitting element 210, and the third light-emitting element 220 are plotted on an xy chromaticity diagram of the CIE1931 color space. A range surrounded by a triangular shape, which is formed as a result of connecting the chromaticity coordinates of the above-described three points, using by straight lines, is the color gamut of the light-emitting device 30. FIG. 4 shows, as a typical example, the color gamut of the light-emitting device 30 obtained when the first light-emitting element 200 in which x=0.05 is used in Example 2-1. In Example 2-1, the chromaticity coordinates (CIEx, CIEy) of the first light-emitting element 200 are (0.150, 0.052), the chromaticity coordinates (CIEx, CIEy) of the second light-emitting element 210 are (0.170, 0.797), and the chromaticity coordinates (CIEx, CIEy) of the third light-emitting element 220 are (0.708, 0.292).

In FIG. 4, the ideal color gamut specified by BT.2020 and the color gamut of the light emitted by the light-emitting device 30 are shown. In FIG. 4, the overlapping section in which the ideal color gamut overlaps with the color gamut of the light emitted from the light-emitting device 30 is shown by hatching. The BT.2020 coverage ratio is the proportion, of the area of the ideal color gamut, occupied by the area of the overlapping section. A larger BT.2020 coverage ratio means a wider color gamut of the emitted light.

As a result of calculation using FIG. 4, when x=0.05 in Example 2-1, the BT.2020 coverage ratio is 96.5%. Similarly, in Example 2-1, Example 2-2 and Example 2-3, calculation results of the BT.2020 coverage ratios corresponding to the values of x are shown in FIG. 3. Details of each of the examples will be described below.

### EXAMPLE 2-1

In Example 2-1, which is an example of the second embodiment, the second light-emitting element 210 and the third light-emitting element 220 are light-emitting elements that satisfy ideal values of the color gamut specified by BT.2020.

The second light-emitting element 210 and the third light-emitting element 220 each emit light of a color of the ideal values of the color gamut specified by BT.2020. The chromaticity coordinates (CIEx, CIEy) of the second light-emitting element 210 are (0.170, 0.797), and the second light-emitting element 210 is a light source that emits light of an ideal green color. The chromaticity coordinates (CIEx, CIEy) of the third light-emitting element 220 are (0.708, 0.292), and the third light-emitting element 220 is a light source that emits light of an ideal red color. In the present example, a configuration and a material that achieve the above-described chromaticity coordinates can be employed as appropriate for the second light-emitting element 210 and the third light-emitting element 220.

In FIG. 3, with respect to the light-emitting device 30 of Example 2-1, the BT.2020 coverage ratios are shown that are obtained when the value of x is changed in a range from x=0 to x=1.

When x=0, the BT.2020 coverage ratio is 95.3%, and when x=1, the BT.2020 coverage ratio is 92.7%.

When x=0.05, the BT.2020 coverage ratio is 96.5%. As x increases, the BT.2020 coverage ratio increases. When x=0.15, the BT.2020 coverage ratio is 98.8% and temporarily indicates a peak value. After that, as x increases, the BT.2020 coverage ratio decreases. When x=0.3, the BT.2020 coverage ratio is 91.3%, and the BT.2020 coverage ratio becomes smaller than the BT.2020 coverage ratio obtained when x=1.

When x=0.35, the BT.2020 coverage ratio is 88.9% and indicates a bottom value. After that, as x increases. the BT.2020 coverage ratio increases again. When x=0.51, the BT.2020 coverage ratio is 93.3%, and the BT.2020 coverage ratio becomes larger than the BT.2020 coverage ratio obtained when x=1.

When x=0.6, the BT.2020 coverage ratio is 98.1% and once more indicates a peak value. After that, as x increases, the BT.2020 coverage ratio once more decreases. After that, until x becomes equal to 1, the BT.2020 coverage ratios indicate values larger than the BT.2020 coverage ratio obtained when x=1.

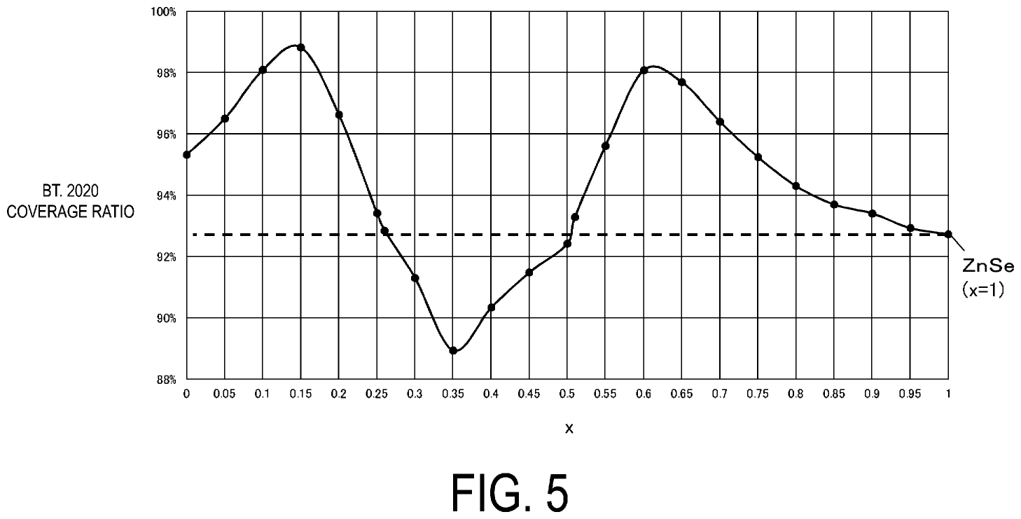

FIG. 5 is a diagram in which coordinates, which are combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots is ZnSe, the BT.2020 coverage ratio is 92.7%. A contour line of the color gamut of light emitted by ZnSe is indicated by a dotted line in FIG. 5. Even when x changes within a range of 0<x≤0.26 or 0.51≤x<1, the BT.2020 coverage ratio becomes larger than the BT.2020 coverage ratio obtained when x=1.

The peak wavelengths of the light emitted by the first light-emitting element 200 corresponding to the range of 0<x≤0.26 or 0.51≤x<1 fall within a range greater than 394 nm and equal to or less than 474 nm. Thus, in the above-described range of the peak wavelength, the BT.2020 coverage ratio of the light-emitting device 30 can be increased compared to a case in which ZnSe is used, and the color gamut of the light emitted by the light-emitting device 30 is widened. Therefore, using such a type of the first light-emitting element 200, the display device 10 having a wide color gamut of emission light can be manufactured.

### EXAMPLE 2-2

In Example 2-2, which is an example of the second embodiment, the second light-emitting layer 214 of the second light-emitting element 210 includes the plurality of second quantum dots. The third light-emitting layer 224 of the third light-emitting element 220 includes the plurality of third quantum dots. The plurality of second quantum dots and the plurality of third quantum dots contain InP as a main material. The average particle size of the plurality of second quantum dots and the plurality of third quantum dots is a size that causes the peak wavelengths of light emitted by the plurality of second quantum dots and the plurality of third quantum dots, respectively, to be desired peak wavelengths. For example, when the average particle size of the plurality of second quantum dots is from 2.0 nm to 2.5 nm, the desired value of the peak wavelength of the light emission spectrum of the second light-emitting layer 214 is from 510 nm to 540 nm. When the average particle size of the plurality of third quantum dots is from 3.5 nm to 5.0 nm, the desired value of the peak wavelength of the light emission spectrum of the third light-emitting layer 224 is from 620 nm to 690 nm.

In Example 2-2, the chromaticity coordinates (CIEx, CIEy) of the second light-emitting element 210 are (0.270, 0.696), and the chromaticity coordinates (CIEx, CIEy) of the third light-emitting element 220 are (0.677, 0.323). The configuration of the second light-emitting element 210 and the third light-emitting element 220 in the present example is the same as the configuration of the second light-emitting element 210 and the third light-emitting element 220 in Example 2-1 described above, except for the configuration of the second light-emitting layer 214 and the third light-emitting layer 224. Descriptions of the same matters as those of the embodiments and examples described above will be omitted below as appropriate.

In FIG. 3, with respect to the light-emitting device 30 of Example 2-2, the BT.2020 coverage ratios are shown that are obtained when the value of x is changed in a range from x=0 to x=1.

When x=0, the BT.2020 coverage ratio is 72.8%, and when x=1, the BT.2020 coverage ratio is 71.0%.

When x=0.05, the BT.2020 coverage ratio is 73.5%. As x increases, the BT.2020 coverage ratio increases. When x=0.1, the BT.2020 coverage ratio is 74.1% and temporarily indicates a peak value. After that, as x increases, the BT.2020 coverage ratio decreases. When x=0.3, the BT.2020 coverage ratio is 69.8%, and the BT.2020 coverage ratio becomes smaller than the BT.2020 coverage ratio obtained when x=1.

When x=0.35, the BT.2020 coverage ratio is 68.3% and indicates a bottom value. After that, as x increases. the BT.2020 coverage ratio increases again. When x=0.53, the BT.2020 coverage ratio is 71.1%, and the BT.2020 coverage ratio becomes larger than the BT.2020 coverage ratio obtained when x=1.

When x=0.65, the BT.2020 coverage ratio is 73.8% and once more indicates a peak value. After that, as x increases, the BT.2020 coverage ratio once more decreases. After that, until x becomes equal to 1, the BT.2020 coverage ratios indicate values larger than the BT.2020 coverage ratio obtained when x=1.

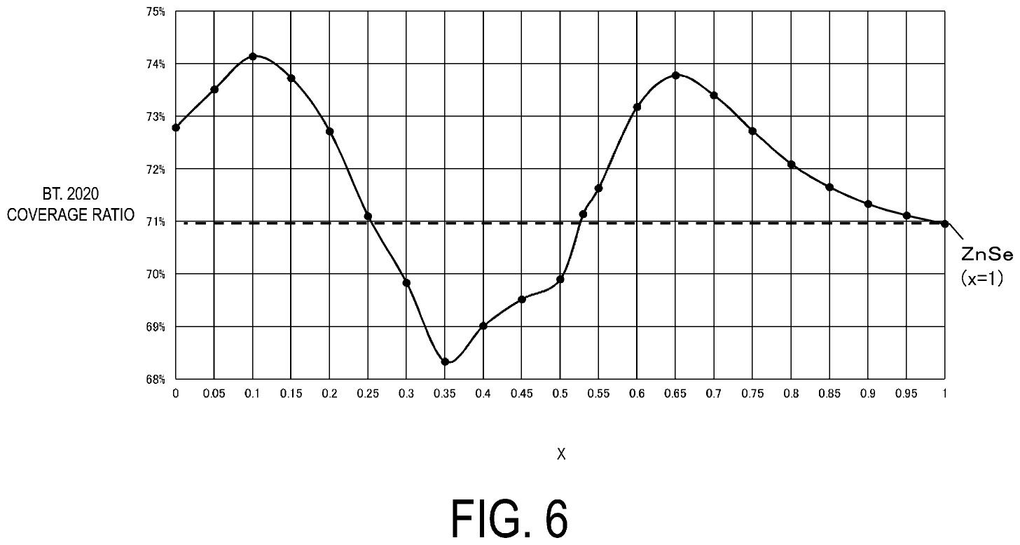

FIG. 6 is a diagram in which the coordinates, which are the combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots is ZnSe, the BT.2020 coverage ratio is 71.0%. The contour line of the color gamut of the light emitted by ZnSe is indicated by a dotted line in FIG. 6. Even when the value of x changes within a range of 0<x≤0.25 and 0.53≤x<1, the BT.2020 coverage ratio becomes larger than the BT.2020 coverage ratio obtained when x=1.

The peak wavelengths of the light emitted by the first light-emitting element 200 corresponding to the range of 0<x≤0.25 or 0.53≤x<1 fall within a range greater than 394 nm and equal to or less than 473 nm. Thus, in the above-described range of the peak wavelength, the BT.2020 coverage ratio of the light-emitting device 30 can be increased compared to a case in which ZnSe is used, and the color gamut of the light emitted by the light-emitting device 30 is widened. Therefore, using such a type of the first light-emitting element 200, the display device 10 having a wide color gamut of emission light can be manufactured.

### EXAMPLE 2-3

In Example 2-3, which is an example of the second embodiment, the second light-emitting layer 214 of the second light-emitting element 210 includes the plurality of second quantum dots, and the material of the plurality of second quantum dots is the compound containing the three elements of Zn, Se, and Te. The third light-emitting layer 224 of the third light-emitting element 220 includes the plurality of third quantum dots, and a composition formula of a compound constituting the plurality of third quantum dots is CuInS₂.

The average particle size and the composition ratio of the plurality of second quantum dots, and the average particle size of the plurality of third quantum dots are set such that the peak wavelengths of the light emitted by the plurality of second quantum dots and the plurality of third quantum dots, respectively, become desired values described below. For example, when the composition of the plurality of second quantum dots is ZnSe_{0.25}Te_{0.75}, if the average particle size is set to be from 3.5 nm to 5.5 nm, the desired value of the peak wavelength of the light emission spectrum of the second light-emitting layer 214 is from 510 nm to 540 nm. The composition ratio of Zn, Se, and Te in the plurality of second quantum dots is not limited to ZnSe_{0.25}Te_{0.75}. The composition ratio of the three elements of Zn, Se, and Te included in the plurality of second quantum dots may be any value, as long as the peak wavelength thereof falls within the above-described range of the peak wavelength. When the average particle size of the plurality of third quantum dots is set to be from 3.4 nm to 4.9 nm, the desired value of the peak wavelength of the light emission spectrum of the third light-emitting layer 224 is from 620 nm to 690 nm.

In Example 2-3, the chromaticity coordinates (CIEx, CIEy) of the second light-emitting element 210 are (0.186, 0.773), and the chromaticity coordinates (CIEx, CIEy) of the third light-emitting element 220 are (0.605, 0.360). The configuration of the second light-emitting element 210 and the third light-emitting element 220 in the present example is the same as the configuration of the second light-emitting element 210 and the third light-emitting element 220 in Example 2-1 described above, except for the configuration of the second light-emitting layer 214 and the third light-emitting layer 224. Descriptions of the same matters as those of the embodiments and examples described above will be omitted below as appropriate.

In FIG. 3, with respect to the light-emitting device 30 of Example 2-3, the BT.2020 coverage ratios are shown that are obtained when the value of x is changed in a range from x=0 to x=1.

When x=0, the BT.2020 coverage ratio is 76.4%, and when x=1, the BT.2020 coverage ratio is 75.2%.

When x=0.05, the BT.2020 coverage ratio is 76.8%. As x increases, the BT.2020 coverage ratio increases again. When x=0.1, the BT coverage ratio is 76.9% and temporarily indicates a peak value. After that, as x increases, the BT.2020 coverage ratio decreases. When x=0.2, the BT.2020 coverage ratio is 75.2%, which becomes equal to the BT.2020 coverage ratio obtained when x=1.

When x=0.35, the BT.2020 coverage ratio is 69.6% and indicates a bottom value. After that, as x increases. the BT.2020 coverage ratio increases again. When x=0.58, the BT.2020 coverage ratio is 75.3%, and the BT.2020 coverage ratio becomes larger than the BT.2020 coverage ratio obtained when x=1.

When x=0.7, the BT.2020 coverage ratio is 76.6% and once more indicates a peak value. After that, as x increases, the BT.2020 coverage ratio once more decreases. After that, until x becomes equal to 1, the BT.2020 coverage ratios indicate values larger than the BT.2020 coverage ratio obtained when x=1.

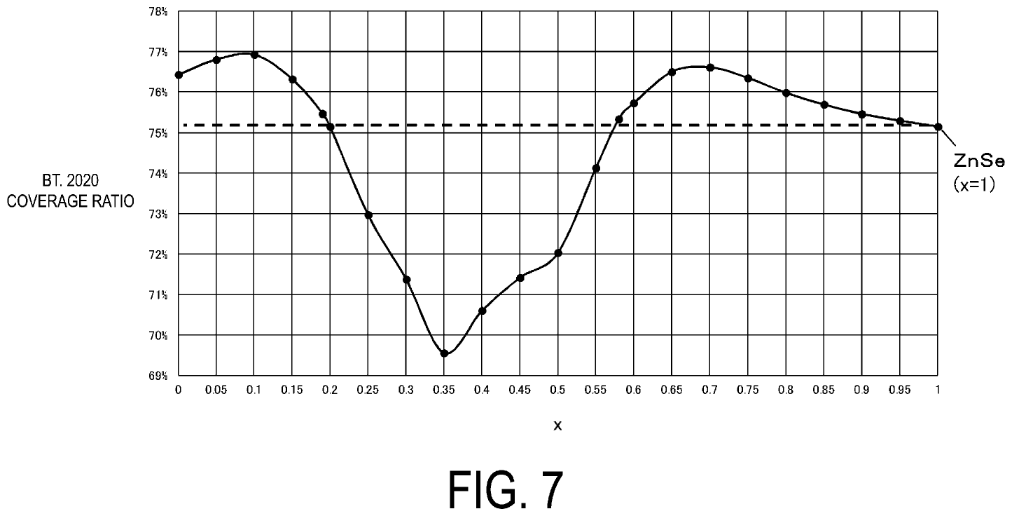

FIG. 7 is a diagram in which the coordinates, which are the combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots is ZnSe, the BT.2020 coverage ratio is 75.2%. The contour line of the color gamut of the light emitted by ZnSe is indicated by a dotted line in FIG. 7. When the value of x is in a range of 0<x≤0.19 and 0.58≤x<1, the BT.2020 coverage ratio becomes larger than the BT.2020 coverage ratio obtained when x=1.

A range of the peak wavelengths of the light emitted by the first light-emitting element 200 corresponding to the values of x within the range of 0<x≤0.19 and 0.58≤x<1 is a range greater than 394 nm and equal to or less than 469 nm. Thus, when the value of x is within the above-described range, the BT.2020 coverage ratio of the light-emitting device 30 can be increased compared to the case in which ZnSe is used, ZnSe being obtained when x=1 in the composition formula of ZnSeₓTe₁₋ₓ, and the color gamut of the light emitted by the light-emitting device 30 is widened. Therefore, using such a type of the first light-emitting element 200, the display device 10 having a wide color gamut of emission light can be manufactured.

### Third Embodiment

A third embodiment of the disclosure will be described below. In the present embodiment, descriptions of the same configurations as those of the first embodiment and the second embodiment will be omitted as appropriate.

In the light-emitting device 30 according to the third embodiment, the average particle size of the plurality of first quantum dots included in the first light-emitting element 200 is 4 nm. The composition formula of the compound constituting the plurality of first quantum dots included in first light-emitting layer 204 is ZnSeₓTe₁₋ₓ, x is a value greater than 0 and smaller than 1. By changing the value of x in the range from 0 to 1, the composition of the compound constituting the plurality of first quantum dots is adjusted.

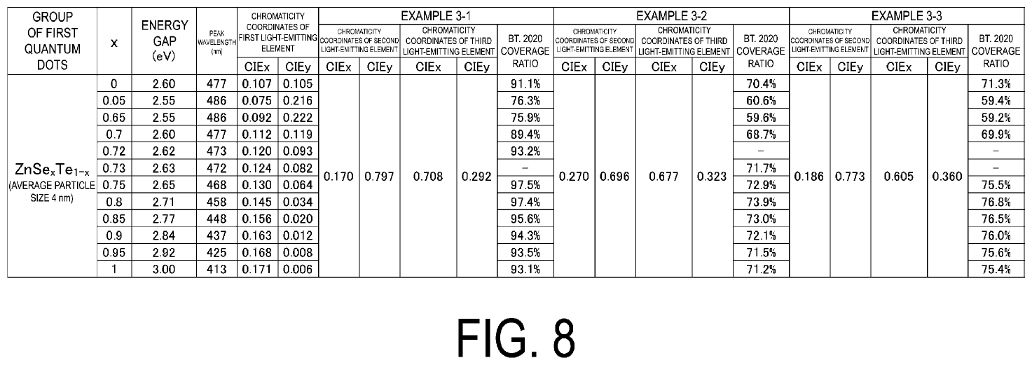

FIG. 8 shows characteristic values of the light emitted by the first light-emitting element 200 when the value of x is changed. The characteristic values of the first light-emitting element 200 shown in FIG. 8 are the same as those shown in FIG. 3.

When x=0, the composition of the plurality of first quantum dots is ZnTe, Eg=2.60 eV, λ=477 nm, and (CIEx, CIEy)=(0.107, 0.105).

When x=0.05, the composition of the plurality of first quantum dots is ZnSe_{0.05}Te_{0.95}, Eg=2.55 eV, λ=486 nm, and (CIEx, CIEy)=(0.075, 0.026).

When x=0.75, the composition of the plurality of first quantum dots is ZnSe_{0.75}Te_{0.25}, Eg=2.65 eV, λ=468 nm , and (CIEx, CIEy)=(0.130, 0.064). In this way, as the value of x changes, the energy gap, the peak wavelength, and the chromaticity coordinates change.

When x=1, the composition of the plurality of first quantum dots is ZnSe, Eg=3.00 eV, λ=413 nm, and (CIEx, CIEy)=(0.171, 0.006).

FIG. 8 shows relationships between the color coordinates and the coverage ratios in Example 3-1, Example 3-2, and Example 3-3, which are each an example of the present embodiment. FIG. 8 shows the chromaticity coordinates (CIEx, CIEy) of the second light-emitting element 210 and the third light-emitting element 220, and the BT.2020 coverage ratios corresponding to the values of x in each of the examples. The light-emitting device 30 that can improve the BT.2020 coverage ratio will be exemplified below.

### EXAMPLE 3-1

In Example 3-1, which is an example of the third embodiment, the second light-emitting element 210 and the third light-emitting element 220 are the light-emitting elements that satisfy the ideal values of the color gamut specified by BT.2020.

In Example 3-1, the second light-emitting element 210 and the third light-emitting element 220 each emit light of a color satisfying the ideal values of the color gamut specified by BT.2020. At this time, the chromaticity coordinates (CIEx, CIEy) of the second light-emitting element 210 are (0.170, 0.797), and the second light-emitting element 210 is the light source that emits the light of the ideal green color. The chromaticity coordinates (CIEx, CIEy) of the third light-emitting element 220 are (0.708, 0.292), and the third light-emitting element 220 is the light source that emits the light of the ideal red color. In the present example, a configuration and a material that achieve the above-described chromaticity coordinates can be employed as appropriate for the second light-emitting element 210 and the third light-emitting element 220.

In FIG. 8, with respect to the light-emitting device 30 of Example 3-1, the BT.2020 coverage ratios are shown that are obtained when the value of x is changed in the range from x=0 to x=1.

When x=0, the BT.2020 coverage ratio is 91.1%, and when x=1, the BT.2020 coverage ratio is 93.1%.

When x=0.05, the BT.2020 coverage ratio is 76.3%, and when x=0.65, the BT.2020 coverage ratio is 75.9%. As x increases, the BT.2020 coverage ratio decreases.

When x=0.65, the BT.2020 coverage ratio is 93.2%. As x increases, the BT.2020 coverage ratio starts increasing. When x=0.75, the BT.2020 coverage ratio is 97.5% and indicates a peak value. After that, as x increases. the BT.2020 coverage ratio decreases. Until x becomes equal to 1, the BT.2020 coverage ratios indicate values larger than the BT.2020 coverage ratio obtained when x=1.

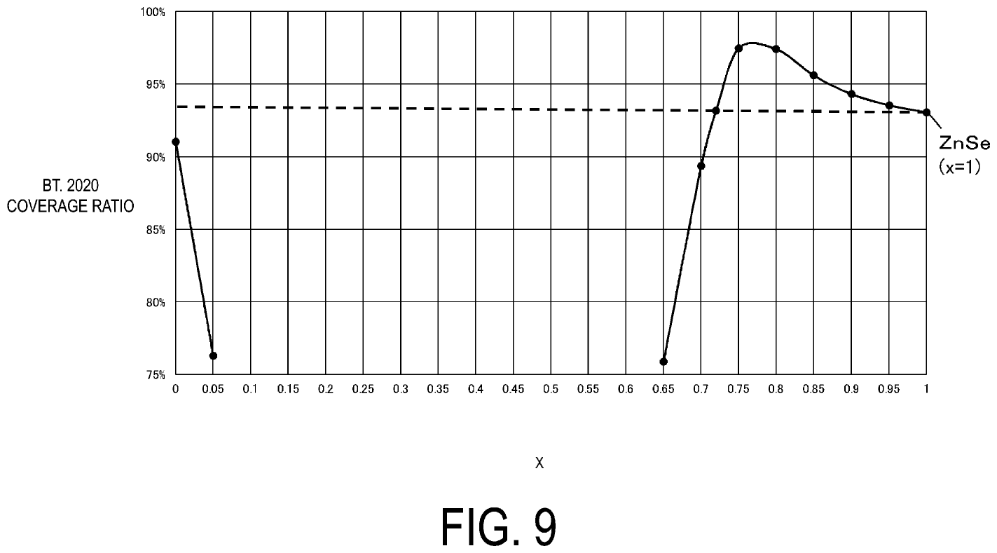

FIG. 9 is a diagram in which the coordinates, which are the combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots becomes ZnSe, the BT.2020 coverage ratio is 91.1%. The contour line of the color gamut of the light emitted by ZnSe is indicated by a dotted line in FIG. 9. Even when the value of x changes within a range of 0.72≤x<1, the BT.2020 coverage ratio becomes larger than the BT.2020 coverage ratio obtained when x=1.

In the range of 0.72≤x<1, a range of the peak wavelengths of the light emitted by the first light-emitting element 200 corresponding to the values of x is a range greater than 413 nm and equal to or less than 473 nm. Thus, in the above-described range, the BT.2020 coverage ratio of the light-emitting device 30 can be increased compared to the case in which ZnSe is used, and the color gamut of the light emitted by the light-emitting device 30 is widened. Therefore, using such a type of the first light-emitting element 200, the display device 10 having a wide color gamut of emission light can be manufactured.

### EXAMPLE 3-2

In Example 3-2, which is an example of the third embodiment, the second light-emitting layer 214 of the second light-emitting element 210 includes the plurality of second quantum dots. The third light-emitting layer 224 of the third light-emitting element 220 includes the plurality of third quantum dots. The plurality of second quantum dots and the plurality of third quantum dots contain InP as a main material. The average particle size of the plurality of second quantum dots and the plurality of third quantum dots is a size that causes the peak wavelengths of light emitted by the plurality of second quantum dots and the plurality of third quantum dots, respectively, to be desired peak wavelengths. For example, when the average particle size of the plurality of second quantum dots is set to be from 2.0 nm to 2.5 nm, the desired value of the peak wavelength of the light emission spectrum of the second light-emitting layer 214 is from 510 nm to 540 nm. When the average particle size of the plurality of third quantum dots is set to be from 3.5 nm to 5.0 nm, the desired value of the peak wavelength of the light emission spectrum of the third light-emitting layer 224 is from 620 nm to 690 nm.

In Example 3-2, the chromaticity coordinates (CIEx, CIEy) of the second light-emitting element 210 are (0.270, 0.696), and the chromaticity coordinates (CIEx, CIEy) of the third light-emitting element 220 are (0.677, 0.323). The configuration of the second light-emitting element 210 and the third light-emitting element 220 in the present example is the same as the configuration of the second light-emitting element 210 and the third light-emitting element 220 in Example 3-1 described above, except for the configuration of the second light-emitting layer 214 and the third light-emitting layer 224. Descriptions of the same matters as those of the embodiments and examples described above will be omitted below as appropriate.

In FIG. 8, with respect to the light-emitting device 30 of Example 3-2, the BT.2020 coverage ratios are shown that are obtained when the value of x is changed in the range from x=0 to x=1.

When x=0, the BT.2020 coverage ratio is 70.4%, and when x=1, the BT.2020 coverage ratio is 71.2%.

When x=0.05, the BT.2020 coverage ratio is 60.6%, and when x=0.65, the BT.2020 coverage ratio is 59.6%. As x increases, the BT.2020 coverage ratio decreases.

When x=0.7, the BT.2020 coverage ratio is 68.7%. As x increases, the BT.2020 coverage ratio starts increasing. When x=0.8, the BT.2020 coverage ratio is 73.9% and indicates a peak value. After that, as x increases. the BT.2020 coverage ratio once more decreases. Until x becomes equal to 1, the BT.2020 coverage ratios indicate values larger than the BT.2020 coverage ratio obtained when x=1.

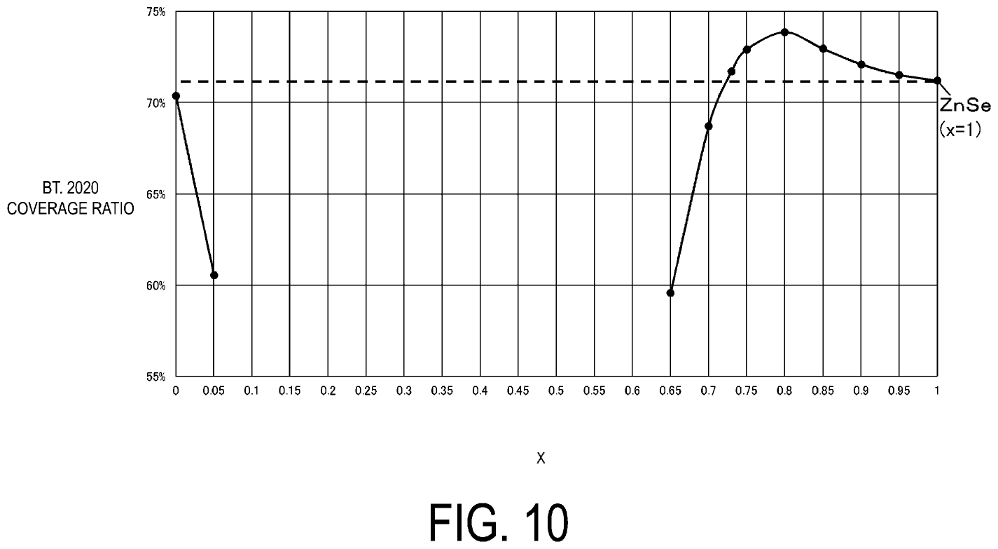

FIG. 10 is a diagram in which the coordinates, which are the combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots becomes ZnSe, the BT.2020 coverage ratio is 71.2%. The contour line of the color gamut of the light emitted by ZnSe is indicated by a dotted line in FIG. 10. Even when the value of x changes within a range of 0.73≤x<1, the BT.2020 coverage ratio becomes larger than the BT.2020 coverage ratio obtained when x=1.

In the range of 0.73≤x<1, a range of the peak wavelengths of the light emitted by the first light-emitting element 200 corresponding to the values of x is a range greater than 413 nm and equal to or less than 472 nm. Thus, in the above-described range, the BT.2020 coverage ratio of the light-emitting device 30 can be increased compared to the case in which ZnSe is used, and the color gamut of the light emitted by the light-emitting device 30 is widened. Therefore, using such a type of the first light-emitting element 200, the display device 10 having a wide color gamut of emission light can be manufactured.

### EXAMPLE 3-3

In Example 3-3, which is an example of a third embodiment, the second light-emitting layer 214 of the second light-emitting element 210 includes the plurality of second quantum dots, and the material of the plurality of second quantum dots is a compound containing the three elements of Zn, Se, and Te. The third light-emitting layer 224 of the third light-emitting element 220 includes the plurality of third quantum dots, and the composition formula of the compound constituting the plurality of third quantum dots is CuInS₂.

The average particle size and the composition ratio of the plurality of second quantum dots, and the average particle size of the plurality of third quantum dots are set such that the peak wavelengths of the light emitted by the plurality of second quantum dots and the plurality of third quantum dots, respectively, become desired values described below. For example, when the composition of the plurality of second quantum dots is ZnSe_{0.25}Te_{0.75}, if the average particle size is set to be from 3.5 nm to 5.5 nm, the desired value of the peak wavelength of the light emission spectrum of the second light-emitting layer 214 is from 510 nm to 540 nm. The composition ratio of Zn, Se, and Te in the plurality of second quantum dots is not limited to ZnSe_{0.25}Te_{0.75}. The composition ratio of the three elements of Zn, Se, and Te included in the plurality of second quantum dots may be any value as long as the peak wavelength is a value included in the above-described range of the peak wavelength of the light emission spectrum. When the average particle size of the plurality of third quantum dots is set to be from 3.4 nm to 4.9 nm, the desired value of the peak wavelength of the light emission spectrum of the third light-emitting layer 224 is from 620 nm to 690 nm.

In Example 3-3, the chromaticity coordinates (CIEx, CIEy) of the second light-emitting element 210 are (0.270, 0.696), and the chromaticity coordinates (CIEx, CIEy) of the third light-emitting element 220 are (0.677, 0.323). The configuration of the second light-emitting element 210 and the third light-emitting element 220 in the present example is the same as the configuration of the second light-emitting element 210 and the third light-emitting element 220 in Example 3-1 described above, except for the configuration of the second light-emitting layer 214 and the third light-emitting layer 224. Descriptions of the same matters as those of the embodiments and examples described above will be omitted below as appropriate.

In FIG. 8, with respect to the light-emitting device 30 of Example 3-2, the BT.2020 coverage ratios are shown that are obtained when the value of x is changed in the range from x=0 to x=1.

When x=0, the BT.2020 coverage ratio is 71.3%, and when x=1, the BT.2020 coverage ratio is 75.4%.

When x=0.05, the BT.2020 coverage ratio is 59.4%, and when x=0.65, the BT.2020 coverage ratio is 59.2%. As x increases, the BT.2020 coverage ratio decreases.

When x=0.7, the BT.2020 coverage ratio is 69.9%. As x increases, the BT.2020 coverage ratio starts increasing. When x=0.8, the BT.2020 coverage ratio is 76.8% and indicates a peak value. After that, as x increases. the BT.2020 coverage ratio once more decreases. Until x becomes equal to 1, the BT.2020 coverage ratios indicate values larger than the BT.2020 coverage ratio obtained when x=1.

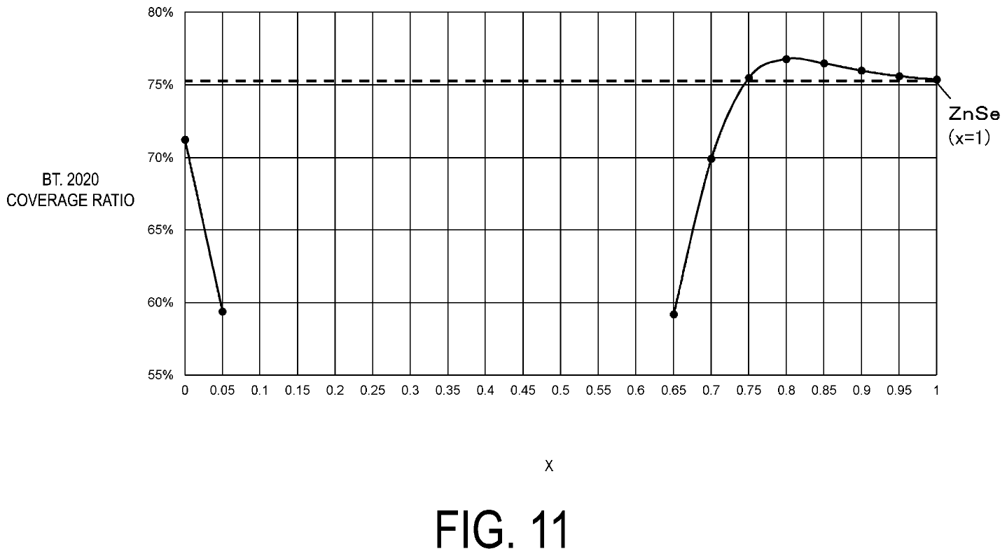

FIG. 11 is a diagram in which the coordinates, which are the combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots becomes ZnSe, the BT.2020 coverage ratio is 75.4%. The contour line of the color gamut of the light emitted by ZnSe is indicated by a dotted line in FIG. 11. Even when the value of x changes within a range of 0.75≤x<1, the BT.2020 coverage ratio becomes larger than the BT.2020 coverage ratio obtained when x=1.

In the range of 0.75≤x<1, a range of the peak wavelengths of the light emitted by the first light-emitting element 200 corresponding to the values of x is a range greater than 413 nm and equal to or less than 468 nm . Thus, in the above-described range, the BT.2020 coverage ratio of the light-emitting device 30 can be increased compared to the case in which ZnSe is used, and the color gamut of the light emitted by the light-emitting device 30 is widened. Therefore, using such a type of the first light-emitting element 200, the display device 10 having a wide color gamut of emission light can be manufactured.

### Fourth Embodiment

A fourth embodiment of the disclosure will be described below. In the present embodiment, descriptions of the same configurations as those of the first to third embodiments will be omitted as appropriate.

In the light-emitting device 30 according to the fourth embodiment, the average particle size of the plurality of first quantum dots included in the first light-emitting element 200 is 5 nm. The composition formula of the compound constituting the plurality of first quantum dots included in first light-emitting layer 204 is ZnSeₓTe₁₋ₓ. x is a value greater than 0 and smaller than 1. By changing the value of x in the range from 0 to 1, the composition of the compound constituting the plurality of first quantum dots is adjusted.

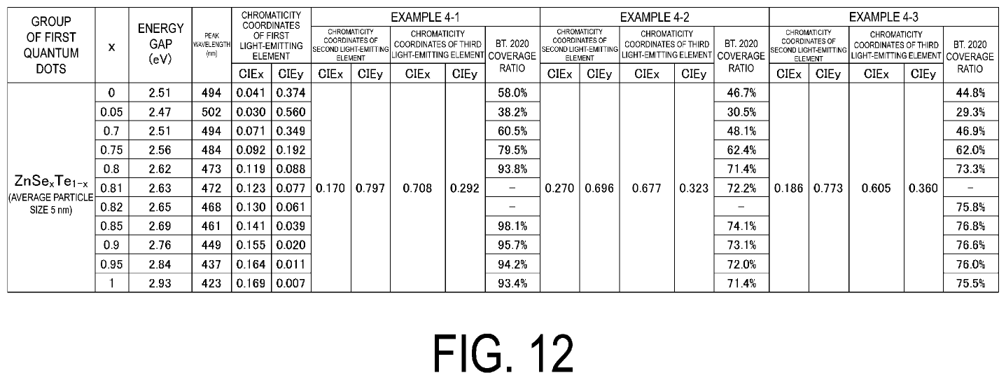

FIG. 12 shows characteristic values of the light emitted by the first light-emitting element 200 when the value of x is changed. The characteristic values of the first light-emitting element 200 shown in FIG. 12 are the same as those shown in FIG. 3 and FIG. 8.

When x=0, the composition of the plurality of first quantum dots is ZnTe, Eg=2.51 eV, λ=494 nm, and (CIEx, CIEy)=(0.041, 0.374).

When x=0.05, the composition of the plurality of first quantum dots is ZnSe_{0.05}Te_{0.95}, Eg=2.47 eV, λ=502 nm, and (CIEx, CIEy)=(0.030, 0.560).

When x=0.7, the composition of the plurality of first quantum dots is ZnSe_{0.75}Te_{0.25}, Eg=2.51 eV, λ=494 nm, and (CIEx, CIEy)=(0.071, 0.349). In this way, as the value of x changes, the energy gap, the peak wavelength, and the chromaticity coordinates change.

When x=1, the composition of the plurality of first quantum dots is ZnSe, Eg=2.93 eV, λ=423 nm, and (CIEx, CIEy)=(0.169, 0.007).

FIG. 12 shows relationships between the color coordinates and the coverage ratios in Example 4-1, Example 4-2, and Example 4-3, which are each an example of the present embodiment. FIG. 12 shows the chromaticity coordinates (CIEx, CIEy) of the second light-emitting element 210 and the third light-emitting element 220, and the BT.2020 coverage ratios corresponding to the values of x in each of the examples. The light-emitting device 30 that can improve the BT.2020 coverage ratio will be exemplified below.

### EXAMPLE 4-1

In Example 4-1, which is an example of the fourth embodiment, the second light-emitting element 210 and the third light-emitting element 220 are the light-emitting elements that satisfy the ideal values of the color gamut specified by BT.2020.

In Example 4-1, the second light-emitting element 210 and the third light-emitting element 220 each emit light of a color satisfying the ideal values of the color gamut specified by BT.2020. At this time, the chromaticity coordinates (CIEx, CIEy) of the second light-emitting element 210 are (0.170, 0.797), and the second light-emitting element 210 is the light source that emits the light of the ideal green color. The chromaticity coordinates (CIEx, CIEy) of the third light-emitting element 220 are (0.708, 0.292), and the third light-emitting element 220 is the light source that emits the light of the ideal red color. In the present example, a configuration and a material that achieve the above-described chromaticity coordinates can be employed for the second light-emitting element 210 and the third light-emitting element 220 as appropriate.

In FIG. 12, with respect to the light-emitting device 30 of Example 4-1, the BT.2020 coverage ratios are shown that are obtained when the value of x is changed in the range from x=0 to x=1.

When x=0, the BT.2020 coverage ratio is 58.0%, and when x=1, the BT.2020 coverage ratio is 93.4%.

When x=0.05, the BT.2020 coverage ratio is 38.2%. As x increases, the BT.2020 coverage ratio decreases.

When x=0.7, the BT.2020 coverage ratio is 60.5%. As x increases, the BT.2020 coverage ratio starts increasing. When x=0.85, the BT.2020 coverage ratio is 98.1% and indicates a peak value. After that, as x increases. the BT.2020 coverage ratio once more decreases. Until x becomes equal to 1, the BT.2020 coverage ratios indicate values larger than the BT.2020 coverage ratio obtained when x=1.

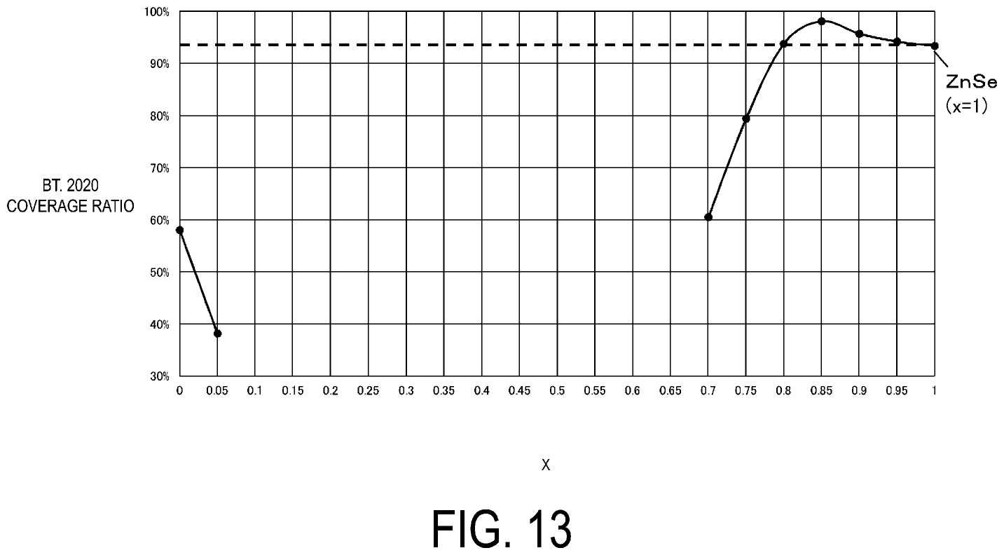

FIG. 13 is a diagram in which the coordinates, which are the combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots becomes ZnSe, the BT.2020 coverage ratio is 93.4%. The contour line of the color gamut of the light emitted by ZnSe is indicated by a dotted line in FIG. 13. Even when the value of x changes within a range of 0.8≤x<1, the BT.2020 coverage ratio becomes larger than the BT.2020 coverage ratio obtained when x=1.

In the range of 0.8≤x<1, a range of the peak wavelengths of the light emitted by the first light-emitting element 200 corresponding to the values of x is a range greater than 423 nm and equal to or less than 473 nm. Thus, in the above-described range, the BT.2020 coverage ratio of the light-emitting device 30 can be increased compared to the case in which ZnSe is used, and the color gamut of the light emitted by the light-emitting device 30 is widened. Therefore, using such a type of the first light-emitting element 200, the display device 10 having a wide color gamut of emission light can be manufactured.

### EXAMPLE 4-2

In Example 4-2, which is an example of the fourth embodiment, the second light-emitting layer 214 of the second light-emitting element 210 includes the plurality of second quantum dots. The third light-emitting layer 224 of the third light-emitting element 220 includes the plurality of third quantum dots. The plurality of second quantum dots and the plurality of third quantum dots contain InP as a main material. The average particle size of the plurality of second quantum dots and the plurality of third quantum dots is a size that causes the peak wavelengths of light emitted by the plurality of second quantum dots and the plurality of third quantum dots, respectively, to be desired peak wavelengths. For example, when the average particle size of the plurality of second quantum dots is set to be from 2.0 nm to 2.5 nm, the desired value of the peak wavelength of the light emission spectrum of the second light-emitting layer 214 is from 510 nm to 540 nm. When the average particle size of the plurality of third quantum dots is set to be from 3.5 nm to 5.0 nm, the desired value of the peak wavelength of the light emission spectrum of the third light-emitting layer 224 is from 620 nm to 690 nm.

In Example 3-2, the chromaticity coordinates (CIEx, CIEy) of the second light-emitting element 210 are (0.270, 0.696), and the chromaticity coordinates (CIEx, CIEy) of the third light-emitting element 220 are (0.677, 0.323). The configuration of the second light-emitting element 210 and the third light-emitting element 220 in the present example is the same as the configuration of the second light-emitting element 210 and the third light-emitting element 220 in Example 3-1 described above, except for the configuration of the second light-emitting layer 214 and the third light-emitting layer 224. Descriptions of the same matters as those of the embodiments and examples described above will be omitted below as appropriate.

In FIG. 12, with respect to the light-emitting device 30 of Example 4-2, the BT.2020 coverage ratios are shown that are obtained when the value of x is changed in the range from x=0 to x=1.

When x=0, the BT.2020 coverage ratio is 46.7%, and when x=1, the BT.2020 coverage ratio is 71.4%.

When x=0.05, the BT.2020 coverage ratio is 30.5%. As x increases, the BT.2020 coverage ratio decreases.

When x=0.7, the BT.2020 coverage ratio is 48.1%. As x increases, the BT.2020 coverage ratio starts increasing. When x=0.85, the BT.2020 coverage ratio is 74.1% and indicates a peak value. After that, as x increases. the BT.2020 coverage ratio once more decreases. Until x becomes equal to 1, the BT.2020 coverage ratios indicate values larger than the BT.2020 coverage ratio obtained when x=1.

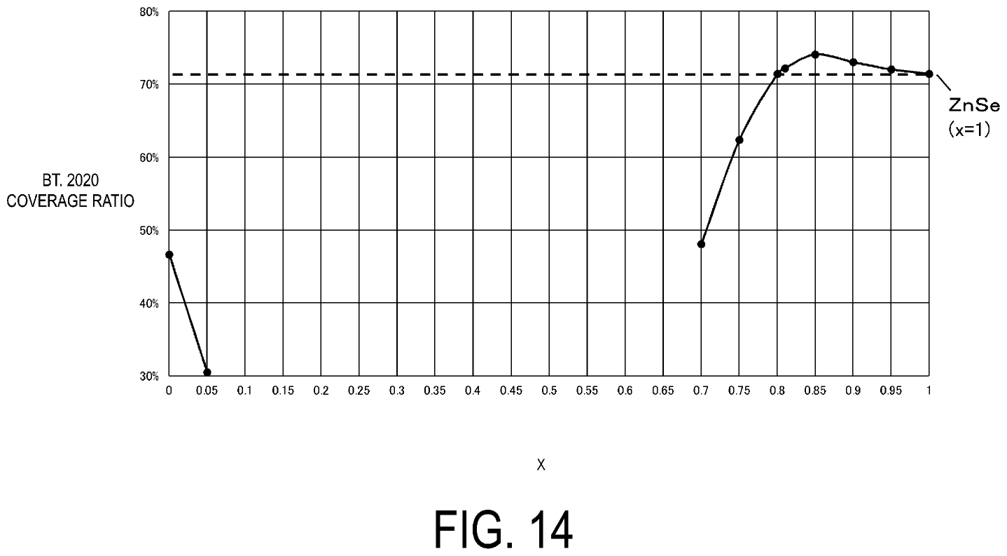

FIG. 14 is a diagram in which the coordinates, which are the combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots becomes ZnSe, the BT.2020 coverage ratio is 71.4%. The contour line of the color gamut of the light emitted by ZnSe is indicated by a dotted line in FIG. 14. Even when the value of x changes within a range of 0.81≤x<1, the BT.2020 coverage ratio becomes larger than the BT.2020 coverage ratio obtained when x=1.

In the range of 0.81≤x<1, a range of the peak wavelengths of the light emitted by the first light-emitting element 200 corresponding to the values of x is a range greater than 423 nm and equal to or less than 472 nm. Thus, in the above-described range, the BT.2020 coverage ratio of the light-emitting device 30 can be increased compared to the case in which ZnSe is used, and the color gamut of the light emitted by the light-emitting device 30 is widened. Therefore, using such a type of the first light-emitting element 200, the display device 10 having a wide color gamut of emission light can be manufactured.

### EXAMPLE 4-3

In Example 4-3, which is an example of the fourth embodiment, the second light-emitting layer 214 of the second light-emitting element 210 includes the plurality of second quantum dots, and the material of the plurality of second quantum dots is a compound containing the three elements of Zn, Se, and Te. The third light-emitting layer 224 of the third light-emitting element 220 includes the plurality of third quantum dots, and the composition formula of the compound constituting the plurality of third quantum dots is CuInS₂.

The average particle size and the composition ratio of the plurality of second quantum dots, and the particle diameter of the plurality of third quantum dots are set such that the peak wavelengths of the light emitted by the plurality of second quantum dots and the plurality of third quantum dots, respectively, become desired values described below. For example, when the composition of the plurality of second quantum dots is ZnSe_{0.25}Te_{0.75}, if the average particle size of the plurality of second quantum dots is set to be from 3.5 nm to 5.5 nm, the desired value of the peak wavelength of the light emission spectrum of the second light-emitting layer 214 is from 510 nm to 540 nm. The composition ratio of Zn, Se, and Te in the plurality of second quantum dots is not limited to ZnSe_{0.25}Te_{0.75}. The composition ratio of the three elements of Zn, Se, and Te included in the plurality of second quantum dots may be any value as long as the peak wavelength is a value included in the above-described range of the peak wavelength of the light emission spectrum. When the average particle size of the plurality of third quantum dots is set to be from 3.4 nm to 4.9 nm, the desired value of the peak wavelength of the light emission spectrum of the third light-emitting layer 224 is from 620 nm to 690 nm.

In Example 4-3, the chromaticity coordinates (CIEx, CIEy) of the second light-emitting element 210 are (0.270, 0.696), and the chromaticity coordinates (CIEx, CIEy) of the third light-emitting element 220 are (0.677, 0.323). The configuration of the second light-emitting element 210 and the third light-emitting element 220 in the present example is the same as the configuration of the second light-emitting element 210 and the third light-emitting element 220 in Example 4-1 described above, except for the configuration of the second light-emitting layer 214 and the third light-emitting layer 224. Descriptions of the same matters as those of the embodiments and examples described above will be omitted below as appropriate.

In FIG. 12, with respect to the light-emitting device 30 of Example 4-3, the BT.2020 coverage ratios are shown that are obtained when the value of x is changed in the range from x=0 to x=1.

When x=0, the BT.2020 coverage ratio is 44.8%, and when x=1, the BT.2020 coverage ratio is 75.5%.

When x=0.05, the BT.2020 coverage ratio is 29.3%. As x increases, decreases.

When x=0.7, the BT.2020 coverage ratio is 46.9%. As x increases, the BT.2020 coverage ratio starts increasing. When x=0.85, the BT.2020 coverage ratio is 76.8% and indicates a peak value. After that, as x increases. the BT.2020 coverage ratio once more decreases. Until x becomes equal to 1, the BT.2020 coverage ratios indicate values larger than the BT.2020 coverage ratio obtained when x=1.

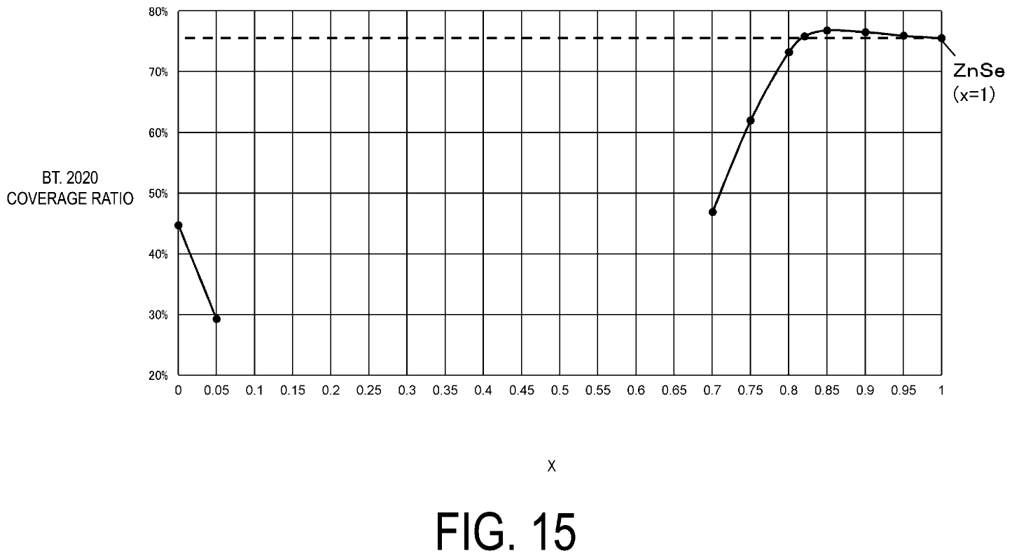

FIG. 15 is a diagram in which the coordinates, which are the combinations of the value of x and the BT.2020 coverage ratio, are plotted on the paper on which only the coordinate axes are depicted, with the value of x being the value of the horizontal axis and the BT.2020 coverage ratio of the present example being the value of the vertical axis. When x=1, namely, when the compound included in the plurality of first quantum dots becomes ZnSe, the BT.2020 coverage ratio is 75.5%. The contour line of the color gamut of the light emitted by ZnSe is indicated by a dotted line in FIG. 15. Even when the value of x changes within a range of 0.82≤x<1, the BT.2020 coverage ratio becomes larger than the BT.2020 coverage ratio obtained when x=1.

In the range of 0.82≤x<1, a range of the peak wavelengths of the light emitted by the first light-emitting element 200 corresponding to the values of x is a range greater than 423 nm and equal to or less than 468 nm . Thus, in the above-described range, the BT.2020 coverage ratio of the light-emitting device 30 can be increased compared to the case in which ZnSe is used, and the color gamut of the light emitted by the light-emitting device 30 is widened. Therefore, using such a type of the first light-emitting element 200, the display device 10 having a wide color gamut of emission light can be manufactured.

The present invention is not limited to the embodiments described above. Embodiments obtained by modifying above-described embodiments and embodiments obtained by appropriately combining technical approaches disclosed in above-described embodiments also fall within the scope of the technology of the present invention.

### REFERENCE SIGNS LIST

10 Display device
20 Light-emitting element
21 Anode electrode
26 Cathode electrode
200 First light-emitting element
204 First light-emitting layer
210 Second light-emitting element
214 Second light-emitting layer
220 Third light-emitting element
224 Third light-emitting layer
30 Light-emitting device

1. A light-emitting element comprising:
an anode electrode;
a cathode electrode; and
a first light-emitting layer including a plurality of first quantum dots and configured to emit light of a first color,
wherein the first light-emitting layer is provided between the anode electrode and the cathode electrode,
each of the plurality of first quantum dots contains a compound containing each of three elements of Zn, Se, Te, and
a combination of an average particle size of the plurality of first quantum dots and a composition ratio of the three elements is selected to cause a peak wavelength of a light emission spectrum of the first light-emitting layer to be greater than 394 nm and equal to or less than 474 nm.

2. The light-emitting element according to claim 1,
wherein the compound is substantially composed of the three elements of Zn, Se and Te and contains unavoidable impurities.

3. (canceled)

4. The light-emitting element according to claim 1,
wherein the peak wavelength of the light emission spectrum of the first light-emitting layer is greater than 413 nm and equal to or less than 473 nm.

5. (canceled)

6. The light-emitting element according to claim 1,
wherein the plurality of first quantum dots contain ZnSeₓTe₁₋ₓ, and
the x is a value within a range of 0<x≤0.26 or 0.51≤x<1.

7. (canceled)

8. (canceled)

9. The light-emitting element according to claim 1,
wherein the average particle size is from 3 nm to 5 nm.

10. A light-emitting device comprising:
a first light-emitting element, the first light-emitting element being the light-emitting element according to claim 1;
a second light-emitting element including a second light-emitting layer configured to emit light of a second color; and
a third light-emitting element including a third light-emitting layer configured to emit light of a third color,
wherein a peak wavelength of a light emission spectrum of the second light-emitting element is from 510 nm to 540 nm, and
a peak wavelength of a light emission spectrum of the third light-emitting element is from 620 nm to 690 nm.

11. A light-emitting device comprising:
a first light-emitting element, the first light-emitting element being the light-emitting element according to claim 1;
a second light-emitting element including a second light-emitting layer including a plurality of second quantum dots containing InP, the second light-emitting layer being configured to emit light of a second color; and
a third light-emitting element including a third light-emitting layer including a plurality of third quantum dots containing InP, the third light-emitting layer being configured to emit light of a third color,
wherein a peak wavelength of a light emission spectrum of the second light-emitting layer is from 510 nm to 540 nm, and
a peak wavelength of a light emission spectrum of the third light-emitting layer is from 620 nm to 690 nm.

12. The light-emitting device according to claim 11,
wherein a combination of the average particle size of the plurality of first quantum dots and the composition ratio of the three elements is selected to cause the peak wavelength of the light emission spectrum of the first light-emitting layer to be greater than 394 nm and equal to or less than 473 nm.

13. The light-emitting device according to claim 12,
wherein a combination of the average particle size of the plurality of first quantum dots and the composition ratio of the three elements is selected to cause the peak wavelength of the light emission spectrum of the first light-emitting layer to be greater than 413 nm and equal to or less than 472 nm.

14. The light-emitting device according to claim 13,
wherein a combination of the average particle size of the plurality of first quantum dots and the composition ratio of the three elements is selected to cause the peak wavelength of the light emission spectrum of the first light-emitting layer to be greater than 423 nm and equal to or less than 472 nm.

15. The light-emitting device according to claim 11,
wherein the plurality of first quantum dots contain ZnSeₓTe₁₋ₓ, and
the x is a value in a range of 0<x≤0.25 or 0.53≤x<1.

16. The light-emitting device according to claim 15,
wherein the x is a value in a range of 0.73≤x<1.

17. The light-emitting device according to claim 16,
wherein the x is a value in a range of 0.81≤x<1.

18. A light-emitting device comprising:
a first light-emitting element, the first light-emitting element being the light-emitting element according to claim 1;
a second light-emitting element including a second light-emitting layer including a plurality of second quantum dots containing a compound composed of three elements of Zn, Se, and Te, the second light-emitting layer being configured to emit light of a second color; and
a third light-emitting element including a third light-emitting layer including a plurality of third quantum dots having a composition of CuInS₂, the third light-emitting layer being configured to emit light of a third color,
wherein a peak wavelength of a light emission spectrum of the second light-emitting element is from 510 nm to 540 nm, and
a peak wavelength of a light emission spectrum of the third light-emitting element is from 620 nm to 690 nm.

19. The light-emitting device according to claim 18,
wherein a combination of the average particle size of the plurality of first quantum dots and the composition ratio of the three elements is selected to cause the peak wavelength of the light emission spectrum of the first light-emitting layer to be greater than 394 nm and equal to or less than 469 nm.

20. The light-emitting device according to claim 19,
wherein a combination of the average particle size of the plurality of first quantum dots and the composition ratio of the three elements is selected to cause the peak wavelength of the light emission spectrum of the first light-emitting layer to be greater than 413 nm and equal to or less than 468 nm.

21. The light-emitting device according to claim 20,
wherein a combination of the average particle size of the plurality of first quantum dots and the composition ratio of the three elements is selected to cause the peak wavelength of the light emission spectrum of the first light-emitting layer to be greater than 423 nm and equal to or less than 468 nm.

22. The light-emitting device according to claim 18,
wherein the plurality of first quantum dots contain ZnSeₓTe₁₋ₓ, and
the x is a value in a range of 0<x≤0.19 or 0.58≤x<1.

23. The light-emitting device according to claim 22,
wherein the x is a value in a range of 0.75≤x<1.

24. (canceled)

25. A display device comprising:
the light-emitting device according to claim 10.
